(19) United States
(12) Patent Application Publication
(10) Pub. No.: US 2024/0206175 A1
(43) Pub. Date: Jun. 20, 2024

(54) Memory Circuitry And Method Used In Forming Memory Circuitry

(71) Applicant: Micron Technology, Inc., Boise, ID (US)

(72) Inventors: Sidhartha Gupta, Boise, ID (US); Adam W. Saxler, Boise, ID (US); Andrew Li, Boise, ID (US); John D. Hopkins, Meridian, ID (US)

(73) Assignee: Micron Technology, Inc., Boise, ID (US)

(21) Appl. No.: 18/540,147

(22) Filed: Dec. 14, 2023

Related U.S. Application Data
(60) Provisional application No. 63/433,923, filed on Dec. 20, 2022.

(51) Int. Cl. H10B 43/27; H10B 41/27

(52) U.S. Cl. CPC H10B 43/27; H10B 41/27

(57) ABSTRACT

A method used in forming memory circuitry comprises forming a stack comprising vertically-alternating first tiers and second tiers directly above a conductor tier. The first tiers comprise sacrificial material and the second tiers comprise non-sacrificial material that is of different composition from that of the sacrificial material. The stack comprises horizontally-elongated trenches extending through the first tiers and the second tiers and are individually between immediately-laterally-adjacent memory-block regions. Channel-material strings are formed that extend through the first and second tiers in the memory-block regions. Through the horizontally-elongated trenches, the sacrificial material is replaced with conductive material that comprises control-gate lines in the memory-block regions. After the replacing, conducting material is formed in a lowest of the first tiers and directly electrically couples together the channel material of the channel-material strings and conductor material of the conductor tier. Other embodiments, including structure, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-4 are diagrammatic cross-sectional views of portions of a construction that will comprise an array of elevationally-extending strings of memory cells in accordance with an embodiment of the invention.

FIGS. 5-31 are diagrammatic sequential sectional, expanded, enlarged, and/or partial views of the construction of FIGS. 1-4, or portions thereof, and/or alternate embodiments in process in accordance with some embodiments of the invention.

### DETAILED DESCRIPTION OF EXAMPLE EMBODIMENTS

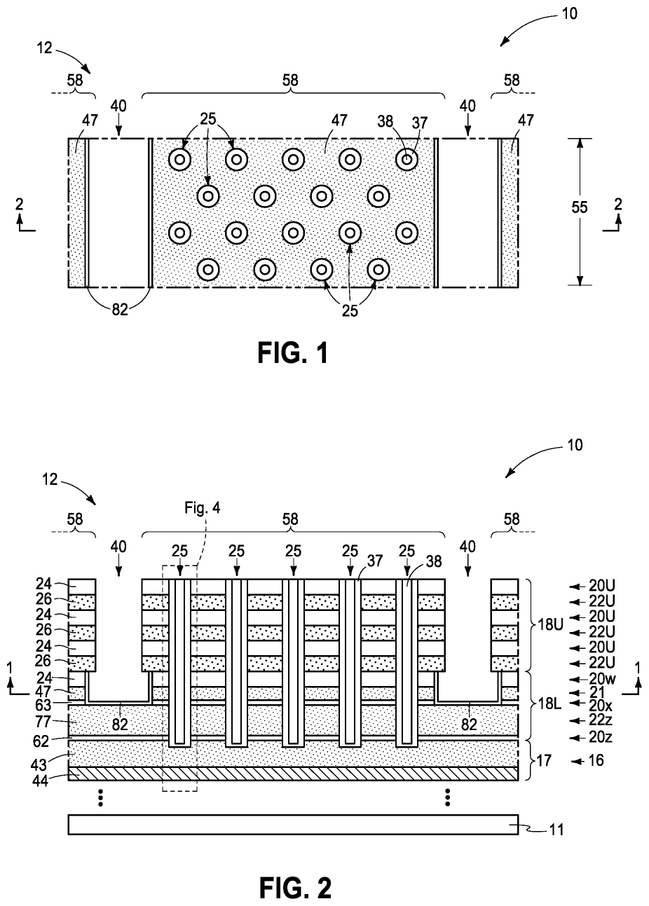

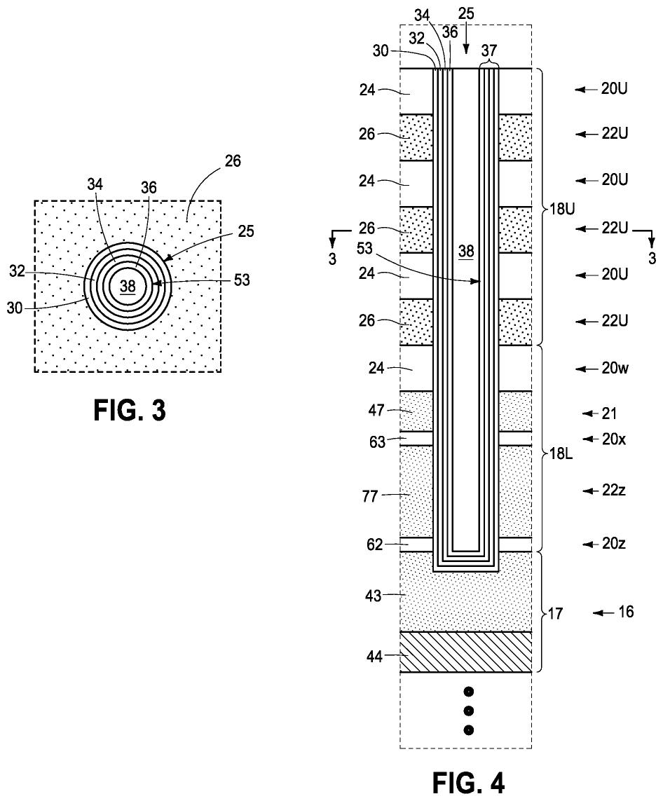

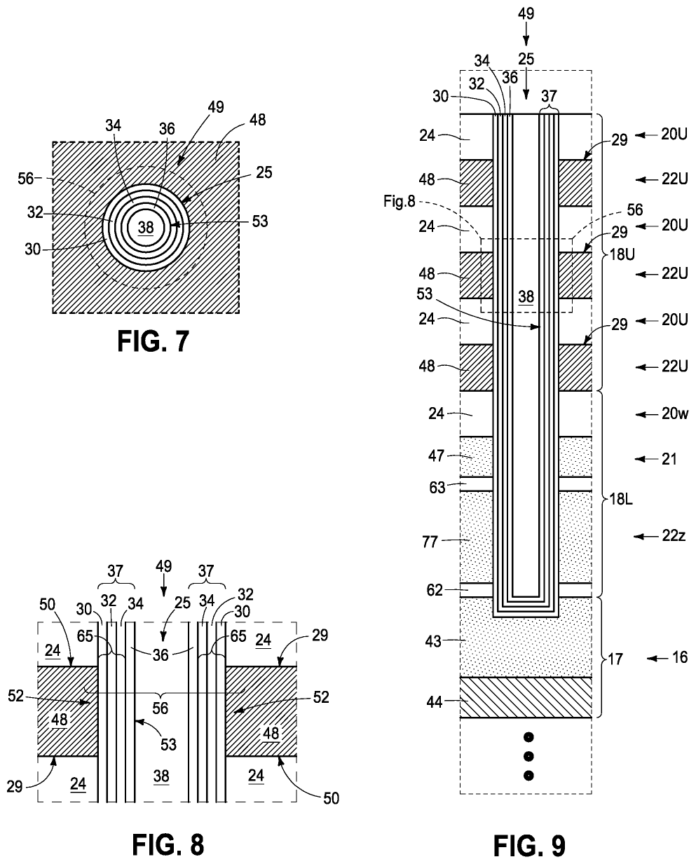

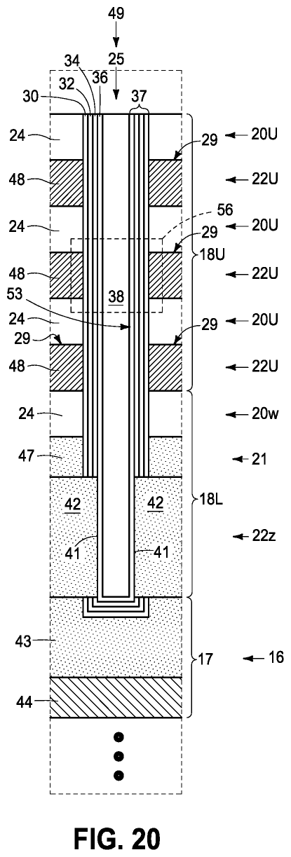

Embodiments of the invention encompass methods used in forming integrated circuitry, for example memory circuitry comprising a memory array, for example an array of NAND or other memory cells that may have at least some peripheral control circuitry under the array (e.g., CMOS-under-array). Embodiments of the invention also encompass integrated circuitry such as that comprising a memory array comprising strings of memory cells (e.g., NAND architecture) independent of method of manufacture. Some example embodiments are described with reference to FIGS. 1-31.

FIGS. 1-4 show an example construction 10 having an array 12 in which elevationally-extending strings of transistors and/or memory cells will be formed. Such includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-4-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 has been formed above substrate 11. Example conductor material 17 comprises upper conductor material 43 directly above and directly electrically coupled to (e.g., directly against) lower conductor material 44 of different composition from upper conductor material 43. An example upper conductor material 43 comprises conductively-doped semiconductive material (e.g., n-type-doped or p-type-doped polysilicon) and an example lower conductor material 44 comprises metal material (e.g., a metal silicide such as WSiₓ). Conductor tier 16 may comprise part of control circuitry (e.g., peripheral-under-array circuitry and/or a common source line or plate) used to control read and write access to the transistors and/or memory cells that will be formed within array 12.

A lower portion 18L of a stack 18* has been formed above substrate 11 and conductor tier 16 (an * being used as a suffix to be inclusive of all such same-numerically-designated components that may or may not have other suffixes). Stack 18* will comprise vertically-alternating conductive tiers 22* and insulative tiers 20*, with material of tiers 22* being of different composition from material of tiers 20*. Stack 18* comprises laterally-spaced memory-block regions 58 that will comprise laterally-spaced memory blocks 58 in a finished-circuitry construction. In this document, unless otherwise indicated, “block” is generic to include “sub-block”. Memory-block regions 58 and resultant memory blocks 58 (not yet shown) may be considered as being longitudinally elongated and oriented, for example along a direction 55. Conductive tiers 22* (alternately referred to as first tiers) may not comprise conducting material and insulative tiers 20* (alternately referred to as second tiers) may not comprise insulative material or be insulative at this point in processing.

Example lower portion 18L comprises a lowest tier 20z of second tiers 20* directly above (e.g., directly against) conductor material 17. Example lowest second tier 20z is insulative and may be sacrificial (e.g., comprising material 62, for example silicon dioxide and/or silicon nitride). A next-lowest second tier 20x of second tiers 20* is directly above lowest second tier 20z and may be sacrificial (e.g., comprising material 63, for example silicon dioxide and/or silicon nitride). In some embodiments, a lowest tier 22z of first tiers 22* comprising sacrifice material 77 (e.g., polysilicon or silicon nitride) is vertically-between lowest second tier 20z and next-lowest second tier 20x. Example lower portion 18L comprises a conducting-material tier 21 comprising conducting material 47 (e.g., conductively-doped polysilicon) that is directly above next-lowest second tier 20x. Example lower portion 18L comprises an upper second tier 20w (e.g., a next-next lowest second tier at least at this point of processing) comprising insulative material 24 (e.g., silicon dioxide). Additional tiers may be present. For example, one or more additional tiers may be above tier 20w (tier 20w thereby not being the uppermost tier in portion 18L, and not shown), between tier 20w and tier 21 (not shown), and/or below tier 22z (other than 20z not being shown).

Example stack 18* comprises an upper portion 18U comprising vertically-alternating first tiers 22U and second tiers 20U formed above lower portion 18L. Material 26 of first tiers 22U (e.g., silicon nitride) is sacrificial and of different composition from a non-sacrificial material 24 of second tiers 20U (e.g., silicon dioxide). Example upper portion 18U is shown starting above lower portion 18L with a first tier 22U although such could alternately start with a second tier 20U (not shown). Further, and by way of example, lower portion 18L may be formed to have one or more first and/or second tiers as a top thereof. Regardless, only a small number of tiers 20U and 22U is shown, with more likely upper portion 18U (and thereby stack 18*) comprising dozens, a hundred or more, etc. of tiers 20* and 22*. Further, other circuitry that may or may not be part of peripheral and/or control circuitry may be between conductor tier 16 and stack 18*. By way of example only, multiple vertically-alternating tiers of conductive material and insulative material of such circuitry may be below a lowest of conductive tiers 22* and/or above an uppermost of conductive tiers 22*. For example, one or more select gate tiers (not shown) may be between conductor tier 16 and the lowest conductive tier 22* and one or more select gate tiers may be above an uppermost of conductive tiers 22*. Alternately or additionally, at least one of the depicted uppermost and lowest conductive tiers 22* may be a select gate tier.

Channel openings 25 have been formed (e.g., by etching) through second tiers 20* and first tiers 22* in upper portion 18U to lower portion 18L (e.g., at least to lowest first tier 22z) in memory-block regions 58. Channel openings 25 may taper radially-inward and/or radially-outward (not shown) moving deeper into stack 18*. In some embodiments, channel openings 25 may go into conductor material 17 of conductor tier 16 as shown or may stop there-atop (not shown). Alternately, as an example, channel openings 25 may stop atop or within the lowest second tier 20z. A reason for extending channel openings 25 at least to conductor material 17 of conductor tier 16 is to provide an anchoring effect to material that is within channel openings 25.

Transistor channel material may be formed in the individual channel openings elevationally along the insulative tiers and the conductive tiers, thus comprising individual channel-material strings, which is directly electrically coupled with conductor material in the conductor tier. Individual memory cells of the example memory array being formed may comprise a gate region (e.g., a control-gate region) and a memory structure laterally-between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally-between the channel material and the storage material.

In one embodiment and as shown, charge-blocking material 30, storage material 32, and charge-passage material 34 have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18* and within individual openings 25 followed by planarizing such back at least to a top surface of stack 18*.

Channel material 36 as a channel-material string 53 has also been formed in channel openings 25 elevationally along insulative tiers 20 and conductive tiers 22. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted to remove materials 30, 32, and 34 from the bases of channel openings 25 (not shown) to expose conductor tier 16 such that channel material 36 is directly against conductor material 17 of conductor tier 16. Such punch etching may occur separately with respect to each of materials 30, 32, and 34 (as shown) or may occur with respect to only some (not shown). Alternately, and by way of example only, no punch etching may be conducted and channel material 36 may be directly electrically coupled to conductor material 17 of conductor tier 16 only by a separate conductive interconnect (not yet shown). Regardless, sacrificial etch-stop plugs (not shown) may be formed in lower portion 18L in horizontal locations where channel openings 25 will be prior to forming upper portion 18U. Channel openings 25 may then be formed by etching materials 24 and 26 to stop on or within the material of the sacrificial plugs, followed by exhuming remaining material of such plugs prior to forming material in channel openings 25. A radially-central solid dielectric material 38 (e.g., spin-on-dielectric, silicon dioxide, and/or silicon nitride) is shown in channel openings 25. Alternately, and by way of example only, the radially-central portion within channel openings 25 may include void space(s) (not shown) and/or be devoid of solid material (not shown).

Horizontally-elongated trenches 40 have been formed (e.g., by anisotropic etching) to extend through first tiers 22* and second tiers 20* in stack 18* and that are individually between immediately-laterally-adjacent memory-block regions 58. Trenches 40 individually extend through upper portion 18U to lowest first tier 22z and expose sacrifice material 77 therein. Trenches 40 may taper laterally-inward or laterally-outward moving deeper into stack 18* or otherwise be of varied width. A sacrificial etch-stop line (not shown) having the same general horizontal outline as individual trenches 40 may be formed in a lower portion of stack 18* prior to forming trenches 40 (e.g., in the example depicted wider lower portions of such trenches). Trenches 40 may then be formed by etching materials 24 and 26 to stop on or within the material of the individual sacrificial lines, followed by exhuming remaining material of such sacrificial lines. A lining 82 may be about such sacrificial etch-stop line and remain as shown.

By way of example and for brevity only, channel openings 25 are shown as being arranged in groups or columns of staggered rows of four and five channel openings 25 per row. Trenches 40 will typically be wider than channel openings 25 (e.g., 3 to 10 times wider). Any alternate existing or future-developed arrangement and construction may be used. Trenches 40 and channel openings 25 may be formed in any order relative the other or at the same time.

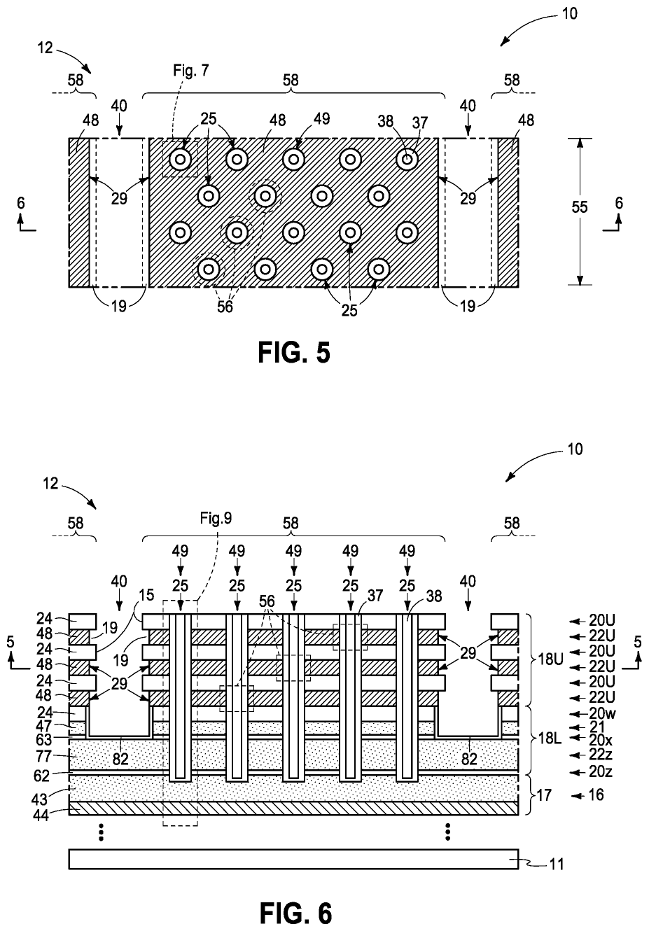

Through the trenches, sacrificial material of the first tiers is replaced with conductive material that comprises control-gate lines in the memory-block regions. For example, and referring to FIGS. 5-9, sacrificial material 26 (not shown) of first tiers 22U has been removed, for example by being isotropically etched away through trenches 40 ideally selectively relative to the other exposed materials (e.g., using liquid or vapor H₃PO₄ as a primary etchant where material 26 is silicon nitride and other materials comprise one or more oxides or polysilicon). Material 26 (not shown) in conductive tiers 22 in the example embodiment is sacrificial and has been replaced with conductive material 48, and which has thereafter been removed from trenches 40, thus forming individual control-gate lines 29 (e.g., wordlines) in stack 18* and elevationally-extending strings 49 of individual transistors and/or memory cells 56 in stack 18*.

A thin insulative liner (e.g., Al₂O₃ and not shown) may be formed before forming conductive material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conductive material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

In one embodiment and as shown, individual control-gate lines 29 have been recessed laterally-inward (e.g., by etching) of sidewalls 15 of insulative material 24 of second tiers 20 that are immediately-directly-above and immediately-directly-below the respective control-gate line and thereby form lateral recesses 19 relative such sidewalls.

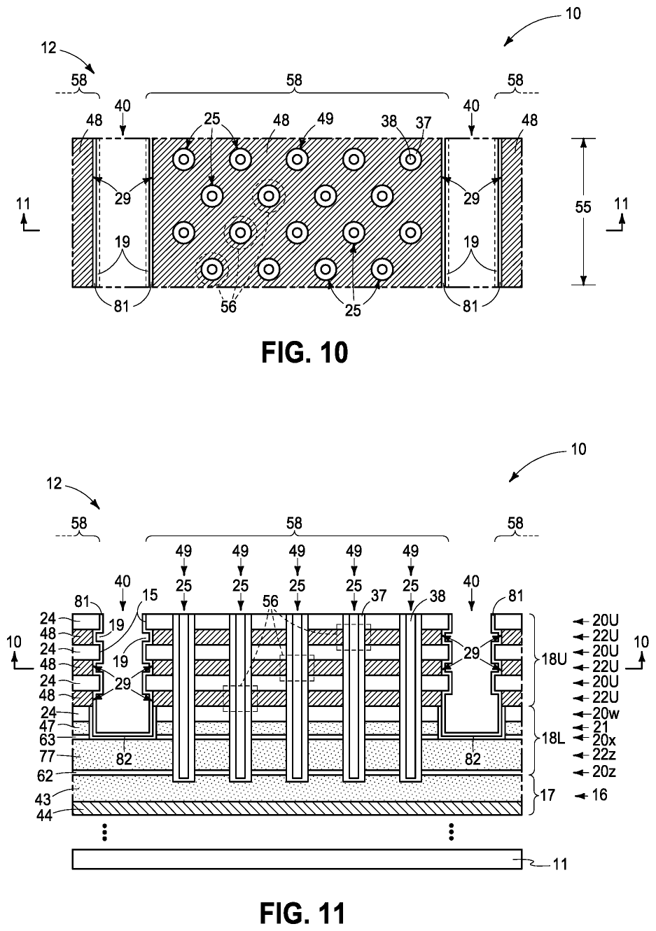

Referring to FIGS. 10 and 11, a laterally-outer insulative lining 81 has been formed in trenches 81 to extend through stack 18U longitudinally-along immediately-laterally-adjacent memory-block regions 58. Any suitable insulative material may be used for lining 81, with silicon nitride being an ideal example (whether stoichiometric, non-stoichiometric, doped, undoped, etc.). In one embodiment where lateral recesses 19 are present, laterally-outer insulative lining 81 is formed to be within such lateral recesses 19 and in one such embodiment less-than-fills such lateral recesses (as shown) and in another embodiment fills such lateral recesses (not shown).

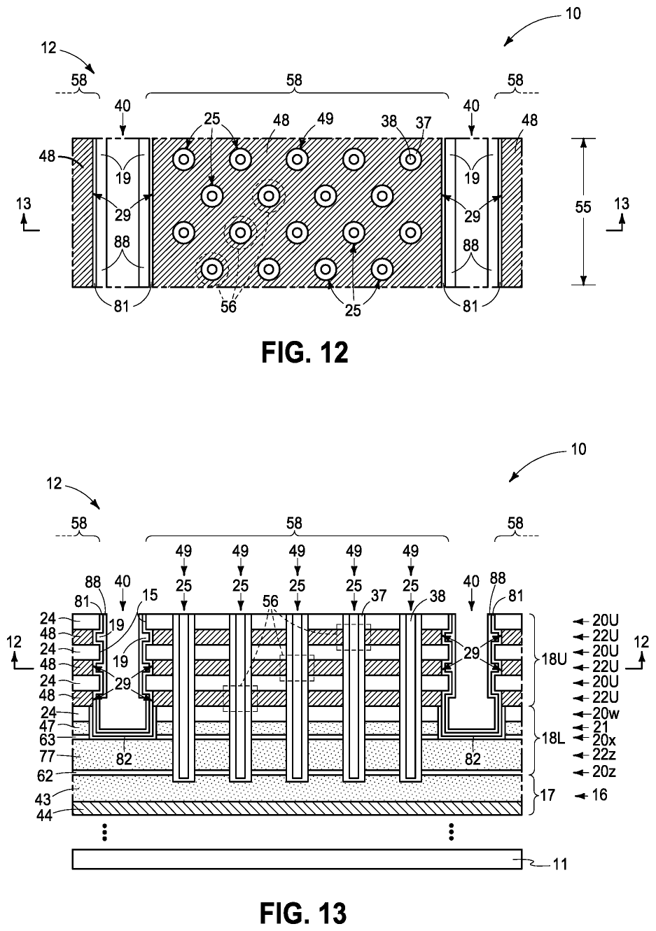

Referring to FIGS. 12 and 13, an optional laterally-inner lining 88 has been formed in trenches 40 (that may or may not fill remaining volume of lateral recesses 19 if/when present). By way of example, such may comprise formation of a silicon dioxide layer followed by formation of a silicon nitride layer followed by formation of a polysilicon layer (not separately shown as part of optional lining 88). Some or all of lining 88 may be sacrificial as will be apparent from the continuing discussion.

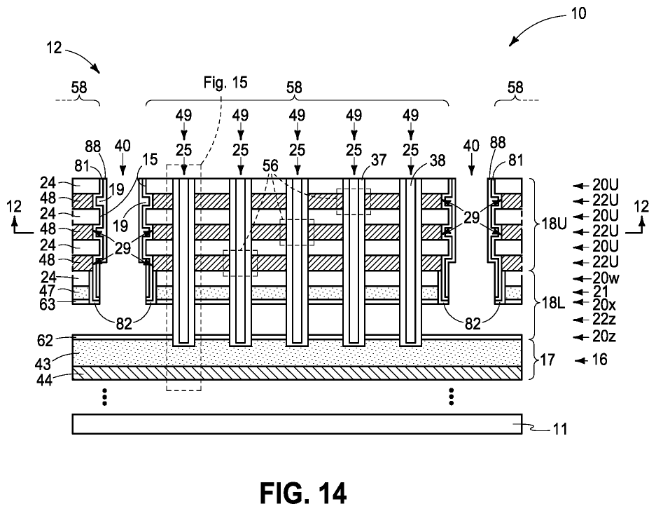

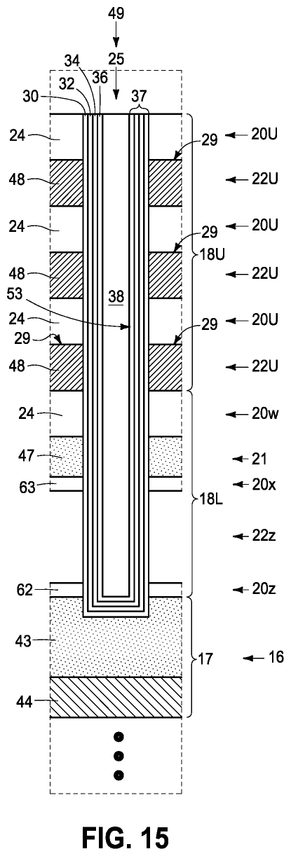

Referring to FIGS. 14 and 15, linings 88, 81 and 82 have been punch-etched to expose lowest first tier 22z. If trenches 40 were initially formed to stop on material 63 (when present), material 63 would correspondingly also be punch-etched such that lowest first tier 22z is exposed. Thereafter, sacrifice material 77 (not shown) has been removed (e.g., by isotropic etching) from lowest first tier 22z through trenches 40, thus leaving or forming a void-space vertically between lowest second tier 20z and next-lowest second tier 20x. Such may occur, for example, by isotropic etching that is ideally conducted selectively relative to materials 62 and 63, for example using liquid or vapor H₃PO₄ as a primary etchant where material 77 is silicon nitride or using tetramethyl ammonium hydroxide [TMAH] where material 77 is polysilicon. In such example and if a laterally-innermost portion of lining 88 comprises polysilicon, such polysilicon would also be removed (not shown).

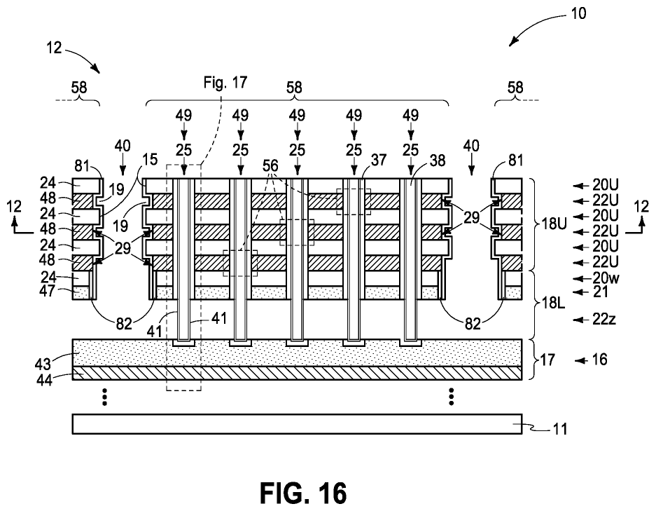

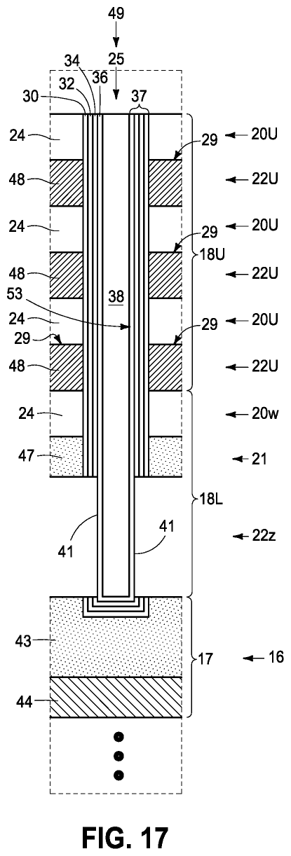

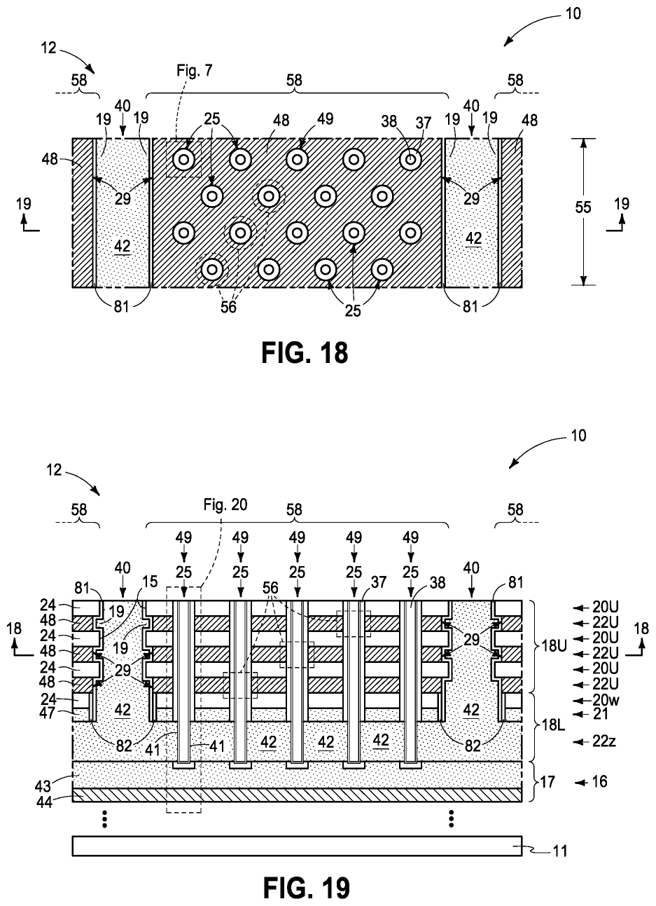

FIGS. 16 and 17 show example subsequent processing wherein, in one embodiment, material 30 (e.g., silicon dioxide), material 32 (e.g., silicon nitride), and material 34 (e.g., silicon dioxide or a combination of silicon dioxide and silicon nitride) have been etched in tier 22z to expose a sidewall 41 of channel material 36 of channel-material strings 53 in lowest first tier 22z. Any of materials 30, 32, and 34 in tier 22z may be considered as being sacrificial material therein. As an example, consider an embodiment where lining 81 (not shown) is one or more insulative oxides (other than solely silicon dioxide) and memory-cell materials 30, 32, and 34 individually are one or more of silicon dioxide and silicon nitride layers. In such example, the depicted construction can result by using modified or different chemistries for sequentially etching silicon dioxide and silicon nitride selectively relative to the other. As examples, a solution of 100:1 (by volume) water to HF will etch silicon dioxide selectively relative to silicon nitride, whereas a solution of 1000:1 (by volume) water to HF will etch silicon nitride selectively relative to silicon dioxide. Accordingly, and in such example, such etching chemistries can be used in an alternating manner where it is desired to achieve the example depicted construction. In one embodiment and as shown, materials 62 and 63 (not shown) have been removed. When so removed, such may be removed when removing materials 30, 32, and 34 are removed, for example if materials 62 and 63 comprise one or both of silicon dioxide and silicon nitride. Alternately, when so removed, such may be removed separately (e.g., by isotropic etching). The artisan is capable of selecting other chemistries for etching other different materials where a construction as shown is desired. If lining 88 (not shown) comprises multiple layers of silicon dioxide and silicon nitride, such may be removed (e.g., by etching) commensurate with removal of materials 30, 32, 34, 62, and 63 where such collectively comprise silicon nitride and silicon dioxide. Alternately, lining 88 may remain at this point of processing (not shown) or be separately or otherwise removed.

Referring to FIGS. 18-20, conducting material 42 (e.g., conductively-doped polysilicon) has been formed in lowest first tier 22z and directly electrically couples together channel material 36 of the channel-material strings 53 and conductor material 17 of the conductor tier 16. Accordingly, and in one embodiment, etched sacrifice material 77 (not shown) has been replaced by conducting material 42 that is directly against sidewalls 41 of channel material 36 of channel-material strings 53. In one embodiment and as shown, conducting material 42 has been formed directly against a bottom of conducting material 47 of conducting-material tier 21 and directly against a top of conductor material 43 of conductor tier 16. Regardless, conducting material 42 may fill all across trenches 40 (as shown) or may not so-fill (not shown) depending on width of trenches 40 compared to height of the void space between materials 43 and 47 and time of deposition of conducting material 42. Conducting material 47 of tier 21 and conducting material 42 of tier 22z being directly against one another may collectively be considered as the lowest conductive tier/lowest first tier that is directly above conductor tier 16.

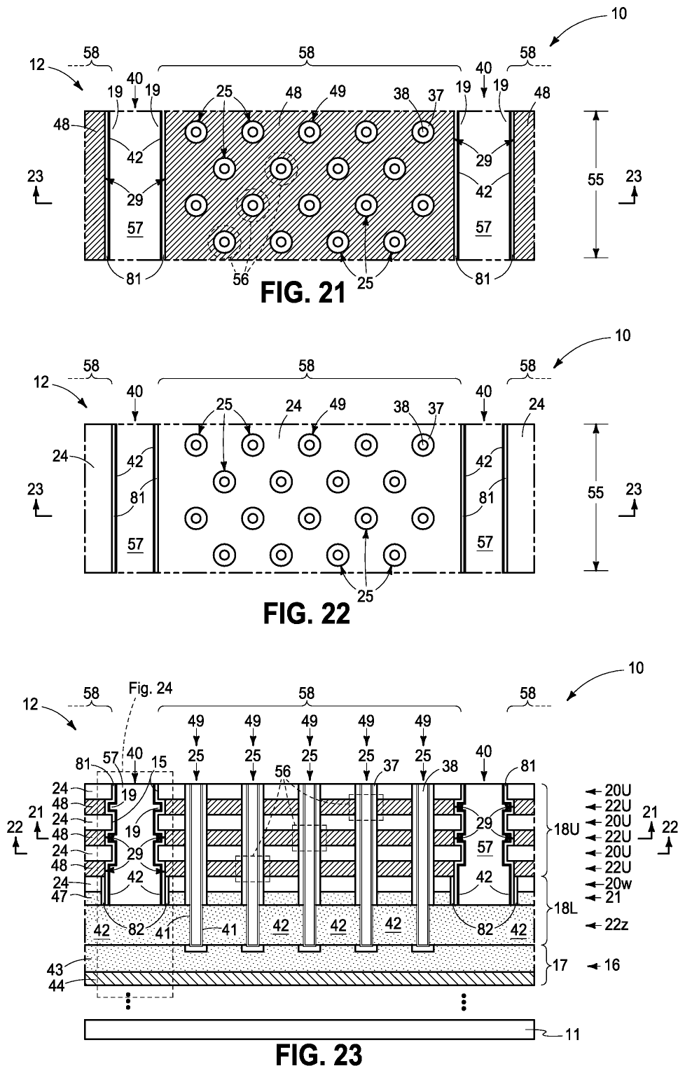

Referring to FIGS. 21-24, conducting material 42 has been removed from trenches 40 downwardly to lowest first tier 22z (at least thereto) (lowest first tier 21/22z) (e.g., using TMAH if conducting material 42 is conductively-doped polysilicon). Thereafter, fill material 57 (e.g., a laterally-outer insulative material such as silicon dioxide having a central polysilicon core laterally -inward thereof) has been formed in trenches 40 and thereby laterally-between and longitudinally-along immediately-laterally-adjacent memory blocks 58. Laterally-outer insulative lining 81 and fill materials 57 may provide lateral electrical isolation (insulation) between immediately-laterally-adjacent memory blocks 58 and facilitate conductive tiers 22 from shorting relative one another in a finished-circuitry construction. Fill material 57 may include through-array vias extending there-through (not shown).

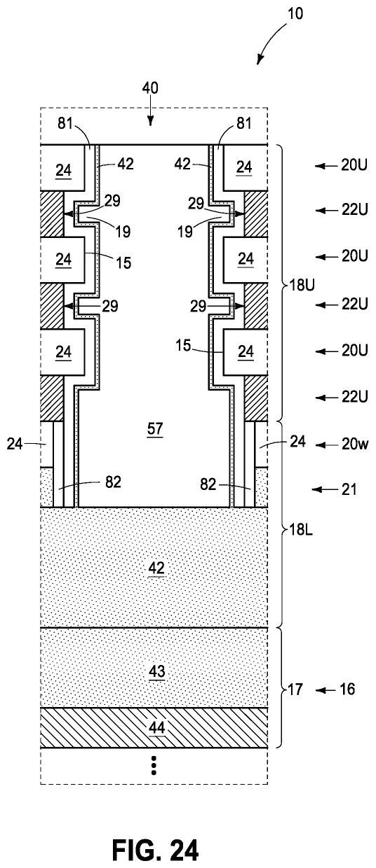

All of conducting material 42 in trenches 40 may be removed above first tier 22z (not shown) or alternately some may remain (as shown). If some of conducting material 42 remains, a combination of laterally-outer insulative lining 81, such some remaining conducting material 42, and fill material 57 collectively comprise intervening material that is laterally-between and longitudinally-along immediately-laterally-adjacent memory-block regions 58. In one embodiment, such some remaining conducting material 42 is laterally-inward of and directly against laterally-outer insulative lining 81 and is vertically-between at least some immediately-vertically-adjacent first tiers 22U. FIGS. 21-24 show an embodiment where such some remaining conducting material 42 is vertically-between all immediately-vertically-adjacent first tiers 22z, in one such embodiment is vertically-continuous from the top of a lower of the immediately-vertically-adjacent first tiers 22U to the bottom of a higher of the immediately-vertically-adjacent first tiers 22U in a vertical cross-section (e.g., that of FIGS. 23 and 24), and in one such embodiment is vertically-continuous from top to bottom of stack 18* in the vertical cross-section. Regardless, such remaining conducting material 42 may be (as shown) or may-not-be (not shown) longitudinally-continuous along trenches 40. Further, FIGS. 21-24 optionally show an example where remaining conducting material 42 is of uniform lateral thickness above first tier 22z.

Any other attribute(s) or aspect(s) as shown and/or described herein with respect to other embodiments may be used in the embodiments shown and described with reference to the above embodiments.

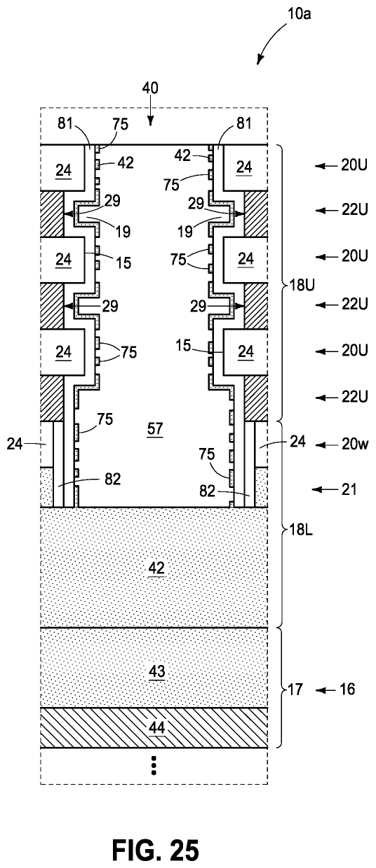

An alternate embodiment construction 10a is shown in FIG. 25. Like numerals from the above-described embodiments have been used where appropriate, with some construction difference being indicated with the suffix “a” or with different numerals. Construction 10a is an example embodiment where remaining conducting material 42 where vertically-between immediately-vertically-adjacent first tiers 22U is not vertically-continuous from the top of a lower of the immediately-vertically-adjacent first tiers 22U to the bottom of a higher of the immediately-vertically-adjacent conductive tiers in the vertical cross-section, and further an example wherein conducting material 42 comprises at least two vertically-spaced segments 75 thereof in the vertical cross-section. Any other attribute(s) or aspect(s) as shown and/or described herein with respect to other embodiments may be used.

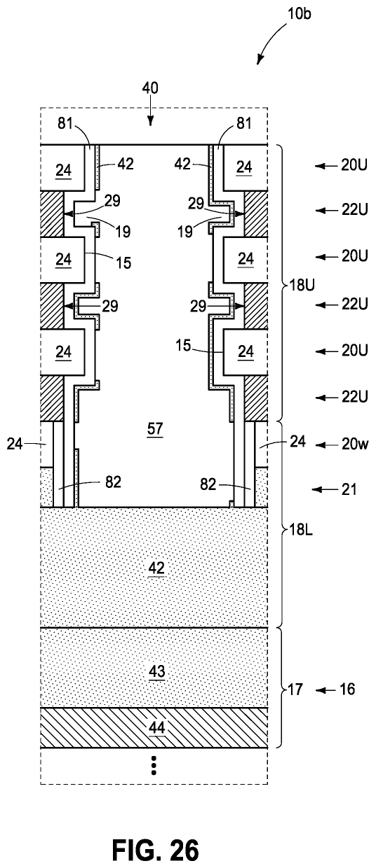

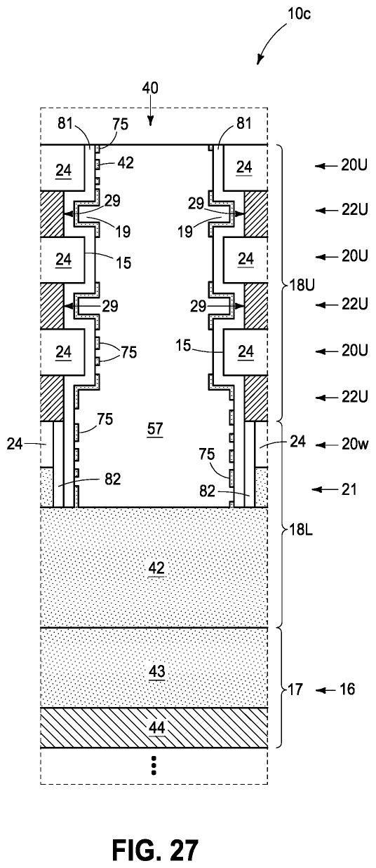

Alternate example embodiment constructions 10b and 10c are shown with respect to FIGS. 26 and 27, respectively. Like numerals from the above-described embodiments have been used where appropriate, with some construction difference being indicated with the suffixes “b” and “c”, respectively, or with different numerals. Each of constructions 10b and 10c is an example where the some conducting material 42 is vertically-between only some immediately-vertically-adjacent conductive tiers 22U. Construction 10b in FIG. 26 is an example where conducting material 42 where vertically-between the only some such first tiers 22 is vertically continuous from top of a lower of the immediately-vertically-adjacent first tiers 22U to bottom of a higher of the immediately-vertically-adjacent first tier 22 in a vertical cross-section (e.g., that of FIG. 26). Construction 10c in FIG. 27 is an example where conducting material 42 where vertically-between the only some first tiers 22U is not so vertically-continuous in the vertical cross-section, and in one such embodiment where conducting material 42 where so vertically-between comprises at least two vertically-spaced segments 75 thereof in the vertical cross-section. Any other attribute(s) or aspect(s) as shown and/or described herein with respect to other embodiments may be used.

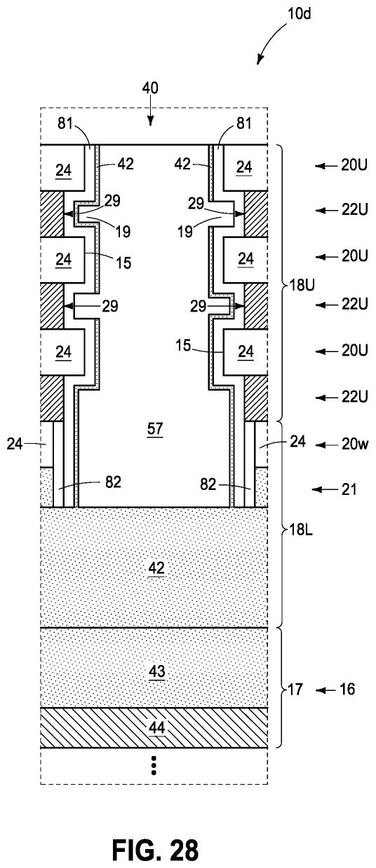

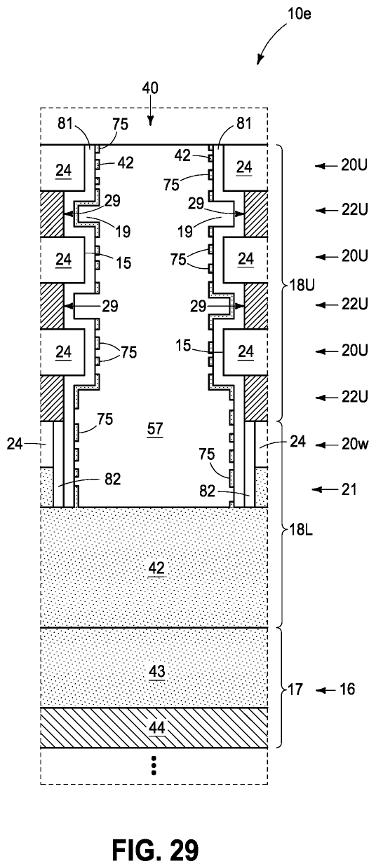

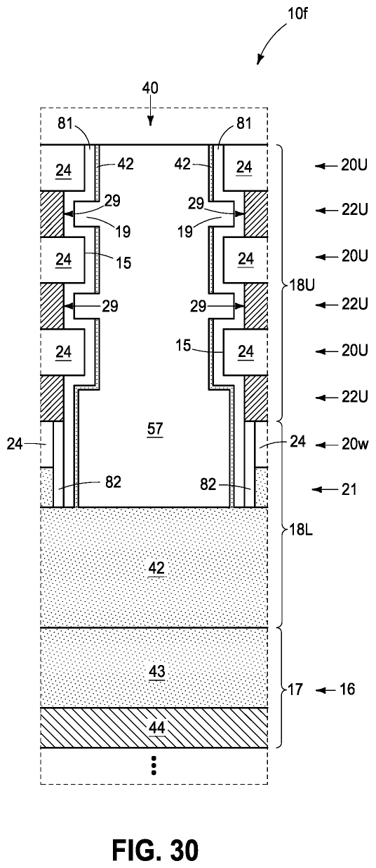

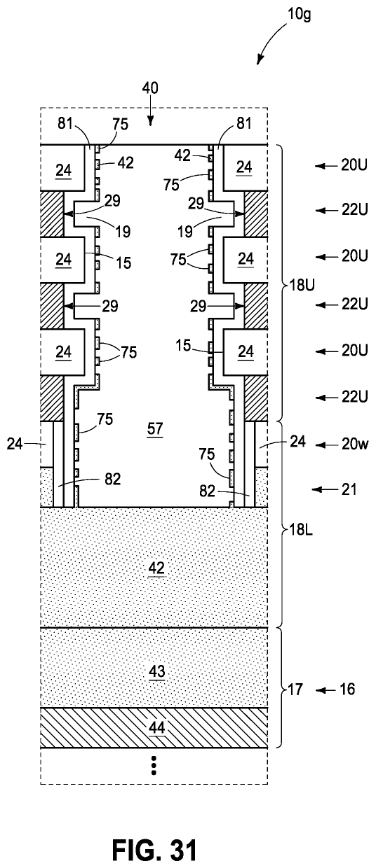

In one embodiment, the remaining some conducting material 42 that is above first tier 22d is in at least some of lateral recesses 19 (when present) laterally-inward of laterally-outer insulative lining 81. Such conducting material 42 may be in only some of lateral recesses 19 (construction 10d in FIG. 28 and construction 10e in FIG. 29) and in another embodiment conducting material 42 is in all of lateral recesses 19 (constructions 10, 10a, 10b, 10c). Alternately, no conducting material 42 may be in any lateral recess 19 (construction 10f in FIG. 30 and construction 10g in FIG. 31). Like numerals from the above-described embodiments have been used where appropriate, with some construction difference being indicated with the suffixes “d”, “e”, “f”, and “g”, respectively, or with different numerals. Regardless, in one embodiment conducting material 42 less-than-fills remaining volume of the at least some lateral recesses in a respective vertical cross-section (as shown), and in another embodiment fills such remaining volume (not shown). Regardless, in some embodiments and as shown, laterally-outer insulative lining 81 is all along floors and ceilings of the at least some lateral recess in a respective vertical cross-section.

Heretofore, in replacement gate processing where directly electrical coupling of channel material 36 to conductor tier 16 occurs through conducting material 42, formation of conducting material 42 occurs before replacing sacrificial material 26 with conductive material 48. This can lead to undesired etching of conducting material 42 when etching sacrificial material 26. Proceeding as disclosed herein can prevent such undesired etching.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 10, 10a, 10b, 10c, 10c, 10d, 10e, 10f, 10g) comprising strings (e.g., 49) of memory cells (e.g., 56) comprises laterally-spaced memory blocks (e.g., 58) individually comprising a vertical stack (e.g., 18*) comprising alternating insulative tiers (e.g., 20) and conductive tiers (e.g., 22) directly above a conductor tier (e.g., 16). Strings of memory cells (e.g., 49) comprise channel-material strings (e.g., 53) that extend through the insulative tiers and the conductive tiers in the memory blocks. The channel-material strings directly electrically couple to conductor material (e.g., 17) of the conductor tier. Intervening material (e.g., 81, 42, and 57) is laterally-between and longitudinally-along immediately-laterally-adjacent of the memory blocks. The intervening material comprises a laterally-outer insulative lining (e.g., 81) extending through the stack (e.g., 18U) longitudinally-along the immediately-laterally-adjacent memory blocks. The intervening material comprises conducting material (e.g., 42) longitudinally-along the immediately-laterally-adjacent memory blocks laterally-inward of and directly against the laterally-outer insulative lining. The conducting material is vertically-between at least some immediately-vertically-adjacent of the conductive tiers. In one embodiment, the conducting material is also below the intervening material in the memory blocks and there directly electrically couples together the channel material of the channel-material strings and the conductor material of the conductor tier. Any other attribute(s) or aspect(s) as shown and/or described herein with respect to other embodiments may be used.

In one embodiment, memory circuitry (e.g., 10, 10a, 10b, 10c, 10c, 10d, 10e, 10f, 10g) comprising strings (e.g., 49) of memory cells (e.g., 56) comprises laterally-spaced memory blocks (e.g., 58) individually comprising a vertical stack (e.g., 18*) comprising alternating insulative tiers (e.g., 20) and conductive tiers (e.g., 22) directly above a conductor tier (e.g., 16). Strings (e.g., 49) of memory cells (e.g., 56) comprising channel-material strings (e.g., 53) extend through the insulative tiers and the conductive tiers in the memory blocks. The channel-material strings directly electrically couple to conductor material (e.g., 17) of the conductor tier. Individual of the conductive tiers comprise a control-gate line (e.g., 29) in individual of the memory blocks. The control-gate line is laterally-recessed inwardly of sidewalls (e.g., 15) of insulative material (e.g., 24) of the insulative tiers that are immediately-directly-above and immediately-directly-below the control-gate line and thereby comprise lateral recesses (e.g., 19) relative such sidewalls. Intervening material (e.g., 81, 42, and 57) is laterally-between and longitudinally-along immediately-laterally-adjacent of the memory blocks. The intervening material comprises a laterally-outer insulative lining (e.g., 81) extending through the stack (e.g., 18U) longitudinally-along the immediately-laterally-adjacent memory blocks. The laterally-outer insulative lining is within and less-than-fills the lateral recesses. Conducting material (e.g., 42) is in at least some of the lateral recesses laterally-inward of the laterally-outer insulative lining. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication processor modems, modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming a stack comprising vertically-alternating first tiers and second tiers directly above a conductor tier. The first tiers comprise sacrificial material and the second tiers comprise non-sacrificial material that is of different composition from that of the sacrificial material. The stack comprises horizontally-elongated trenches extending through the first tiers and the second tiers and are individually between immediately-laterally-adjacent memory-block regions. Channel-material strings are formed that extend through the first and second tiers in the memory-block regions. Through the horizontally-elongated trenches, the sacrificial material is replaced with conductive material that comprises control-gate lines in the memory-block regions. After the replacing, conducting material is formed in a lowest of the first tiers and directly electrically couples together the channel material of the channel-material strings and conductor material of the conductor tier.

In some embodiments, memory circuitry comprising strings of memory cells comprises laterally-spaced memory blocks individually comprising a vertical stack comprising alternating insulative tiers and conductive tiers directly above a conductor tier. Strings of memory cells comprise channel-material strings that extend through the insulative tiers and the conductive tiers in the memory blocks. The channel-material strings directly electrically couple to conductor material of the conductor tier. Intervening material is laterally-between and longitudinally-along immediately-laterally-adjacent of the memory blocks. The intervening material comprises a laterally-outer insulative lining extending through the stack longitudinally-along the immediately-laterally-adjacent memory blocks. Conducting material is longitudinally-along the immediately-laterally-adjacent memory blocks laterally-inward of and directly against the laterally-outer insulative lining. The conducting material is vertically-between at least some immediately-vertically-adjacent of the conductive tiers.

In some embodiments, memory circuitry comprising strings of memory cells comprises laterally-spaced memory blocks individually comprising a vertical stack comprising alternating insulative tiers and conductive tiers directly above a conductor tier. Strings of memory cells comprise channel-material strings that extend through the insulative tiers and the conductive tiers in the memory blocks. The channel-material strings directly electrically couple to conductor material of the conductor tier. Individual of the conductive tiers comprise a control-gate line in individual of the memory blocks. The control-gate line is laterally-recessed inwardly of sidewalls of insulative material of the insulative tiers that are immediately-directly-above and immediately-directly-below the control-gate line and thereby form lateral recesses relative such sidewalls. Intervening material is laterally-between and longitudinally-along immediately-laterally-adjacent of the memory blocks. The intervening material comprises a laterally-outer insulative lining extending through the stack longitudinally-along the immediately-laterally-adjacent memory blocks. The laterally-outer insulative lining is within and less-than-filling the lateral recesses. Conducting material is in at least some of the lateral recesses laterally-inward of the laterally-outer insulative lining.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a stack comprising vertically-alternating first tiers and second tiers directly above a conductor tier, the first tiers comprising sacrificial material and the second tiers comprising non-sacrificial material that is of different composition from that of the sacrificial material, the stack comprising horizontally-elongated trenches extending through the first tiers and the second tiers and that are individually between immediately-laterally-adjacent memory-block regions;
forming channel-material strings that extend through the first and second tiers in the memory-block regions;
through the horizontally-elongated trenches, replacing the sacrificial material with conductive material that comprises control-gate lines in the memory-block regions; and
after the replacing, forming conducting material in a lowest of the first tiers and that directly electrically couples together the channel material of the channel-material strings and conductor material of the conductor tier.

2. The method of claim 1 comprising:
after replacing the sacrificial material and before forming the conducting material in the lowest first tier, etching away sacrifice material from the lowest first tier; and
replacing the etched sacrifice material with the conducting material and that is directly against sidewalls of the channel material of the channel-material strings.

3. The method of claim 1 comprising, after replacing the sacrificial material and before forming the conducting material, forming intervening material in the horizontally-elongated trenches laterally-between and longitudinally-along the immediately-laterally-adjacent memory-block regions, the intervening material comprising:
a laterally-outer insulative lining extending through the stack longitudinally-along the immediately-laterally-adjacent memory-block regions; and
some of the conducting material, the some conducting material being longitudinally-along the immediately-laterally-adjacent memory-block regions laterally-inward of and directly against the laterally-outer insulative lining, the some conducting material being vertically-between at least some immediately-vertically-adjacent of the first tiers.

4. The method of claim 3 wherein the some conducting material is vertically-between only some of the immediately-vertically-adjacent first tiers.

5. The method of claim 4 wherein the some conducting material where vertically-between the only some is vertically-continuous from top of a lower of the immediately-vertically-adjacent first tiers to bottom of a higher of the immediately-vertically-adjacent first tiers in a vertical cross-section.

6. The method of claim 4 wherein the some conducting material where vertically-between the only some is not vertically-continuous from top of a lower of the immediately-vertically-adjacent first tiers to bottom of a higher of the immediately-vertically-adjacent first tiers in the vertical cross-section.

7. The method of claim 6 wherein the some conducting material where vertically-between the only some comprises at least two vertically-spaced segments thereof in the vertical cross-section.

8. The method of claim 3 wherein the some conducting material is vertically-between all of the immediately-vertically-adjacent first tiers.

9. The method of claim 8 wherein the some conducting material where vertically-between the immediately-vertically-adjacent first tiers is vertically-continuous from top of a lower of the immediately-vertically-adjacent first tiers to bottom of a higher of the immediately -vertically-adjacent first tiers in a vertical cross-section.

10. The method of claim 9 wherein the some conducting material is vertically-continuous from top to bottom of the stack in the vertical cross-section.

11. The method of claim 8 wherein the some conducting material where vertically-between the immediately-vertically-adjacent first tiers is not vertically-continuous from top of a lower of the immediately-vertically-adjacent first tiers to bottom of a higher of the immediately-vertically-adjacent first tiers in the vertical cross-section.

12. The method of claim 11 wherein the some conducting material where vertically-between the immediately-vertically-adjacent first tiers comprises at least two vertically-spaced segments thereof in the vertical cross-section.

13. The method of claim 3 wherein the some conducting material is also below the intervening material in the memory blocks and there directly electrically couples together the channel material of the channel-material strings and the conductor material of the conductor tier.

14. The method of claim 1 comprising:
forming individual of the first tiers to comprise a control-gate line in individual of the memory-block regions, the control-gate line being recessed laterally-inward of sidewalls of insulative material of the second tiers that are immediately-directly-above and immediately-directly-below the control-gate line and thereby form lateral recesses relative such sidewalls;
after replacing the sacrificial material and before forming the conducting material, forming intervening material in the horizontally-elongated trenches laterally-between and longitudinally-along immediately-laterally-adjacent of the memory-block regions, the intervening material comprising:
a laterally-outer insulative lining extending through the stack longitudinally-along the immediately-laterally-adjacent memory-block regions, the laterally-outer insulative lining being within and less-than-filling the lateral recesses; and
some of the conducting material, the some conducting material being in at least some of the lateral recesses laterally-inward of the laterally-outer insulative lining.

15. The method of claim 14 wherein the laterally-outer insulative lining is all along floors and ceilings of the at least some lateral recesses in a respective vertical cross-section.

16. The method of claim 14 wherein the some conducting material is in only some of the lateral recesses.

17. The method of claim 14 wherein the some conducting material is in all of the lateral recesses.

18. The method of claim 14 wherein the some conducting material less-than-fills remaining volume of the at least some lateral recesses in a respective vertical cross-section.

19. Memory circuitry comprising strings of memory cells, comprising:
laterally-spaced memory blocks individually comprising a vertical stack comprising alternating insulative tiers and conductive tiers directly above a conductor tier, strings of memory cells comprising channel-material strings that extend through the insulative tiers and the conductive tiers in the memory blocks, the channel-material strings directly electrically coupling to conductor material of the conductor tier; and
intervening material laterally-between and longitudinally-along immediately-laterally-adjacent of the memory blocks, the intervening material comprising:
a laterally-outer insulative lining extending through the stack longitudinally-along the immediately-laterally-adjacent memory blocks; and
conducting material longitudinally-along the immediately-laterally-adjacent memory blocks laterally-inward of and directly against the laterally-outer insulative lining, the conducting material being vertically-between at least some immediately-vertically-adjacent of the conductive tiers.

20. Memory circuitry comprising strings of memory cells, comprising:
laterally-spaced memory blocks individually comprising a vertical stack comprising alternating insulative tiers and conductive tiers directly above a conductor tier, strings of memory cells comprising channel-material strings that extend through the insulative tiers and the conductive tiers in the memory blocks, the channel-material strings directly electrically coupling to conductor material of the conductor tier, individual of the conductive tiers comprising a control-gate line in individual of the memory blocks, the control-gate line being laterally-recessed inwardly of sidewalls of insulative material of the insulative tiers that are immediately-directly-above and immediately-directly-below the control-gate line and thereby forming lateral recesses relative such sidewalls;
intervening material laterally-between and longitudinally-along immediately-laterally-adjacent of the memory blocks, the intervening material comprising:
a laterally-outer insulative lining extending through the stack longitudinally-along the immediately-laterally-adjacent memory blocks, the laterally-outer insulative lining being within and less-than-filling the lateral recesses; and
conducting material in at least some of the lateral recesses laterally-inward of the laterally-outer insulative lining.
